(19) United States
(12) Patent Application Publication
(10) Pub. No.: US 2013/0298969 A1
(43) Pub. Date: Nov. 14, 2013

(54) SOLAR MODULE

(71) Applicant: AU OPTRONICS CORPORATION, Hsin-Chu (TW)

(72) Inventors: Yi-Chia CHEN, HSIN-CHU (TW); Chun-Han TAI, HSIN-CHU (TW); Kuan-Wen TUNG, HSIN-CHU (TW); Ming-Yuan HUANG, HSIN-CHU (TW)

(73) Assignee: AU OPTRONICS CORPORATION, HSIN-CHU (TW)

(21) Appl. No.: 13/760,150

(22) Filed: Feb. 6, 2013

(30) Foreign Application Priority Data
May 9, 2012 (CN) 201210142060.8

(51) Int. Cl. H01L 31/042; H01L 31/048

(52) U.S. Cl. CPC H01L 31/0422; H01L 31/048
USPC 136/251

(57) ABSTRACT

A solar module is provided and includes a support element, a frame body, a photoelectric conversion module, and a protection element. An accommodating space is formed in a region surrounded by the frame body. The photoelectric conversion module is located in the accommodating space. The support element extends past the photoelectric conversion module and is connected to the frame body. The protection element is located on the photoelectric conversion module, and is located in the accommodating space.

### RELATED APPLICATIONS

This application claims priority to China Application Serial Number 201210142060.8, filed May 9, 2012, which is herein incorporated by reference.

### BACKGROUND

1. Technical Field

The present disclosure relates to a solar module, and more particularly to a solar module which does not include a protection glass.

2. Description of Related Art

Solar modules can convert light energy (typically sunlight) into electrical energy. Since solar modules do not produce greenhouse gases during the conversion process, the energy generated by solar modules may be considered a form of green energy. Recently, along with the progress and development in photovoltaic technology, the cost of solar modules has significantly reduced, rendering solar modules more popular in the consumer market. For example, solar modules are now often seen on residence rooftops and on the external walls of buildings, as well as in various electronic products.

FIG. 1 is a cross-sectional view of a conventional solar module 100. As shown in FIG. 1, the solar module 100 includes a solar cell 110, two package layers 120, 130, a protection glass 140, a backboard 150, and a frame 160. The two package layers 120, 130 are respectively located on the top and bottom sides of the solar cell 110. The protection glass 140 and the backboard 150 can prevent moisture from entering the two package layers 120, 130, such that the solar cell 110 is not damaged by moisture during operation. Furthermore, the edges of the solar cell 110, the two package layers 120, 130, the protection glass 140, and the backboard 150 are fixed in a fastening groove 162 of the frame 160.

The protection glass 140 of the conventional solar module 100 protects against moisture, and also improves the rigidity of the solar module 100. Therefore, the solar module 100 is not easily broken in the frame 160. However, since the protection glass 140 is used as a tempered glass, the thickness thereof is typically more than 3 mm, thereby making the weight of the protection glass 140 high. For example, when the size of the protection glass 140 is 1644 mm×984 mm (length×width), the weight of the protection glass 140 may be 15 kg. As a result, the overall weight of the solar module 100 is not easily reduced, such that difficulties are encountered with respect to installing the solar module 100. Moreover, although the protection glass 140 can improve the rigidity of the solar module 100, the flexibility of glass material is bad. When the solar module 100 is used in a harsh environment (e.g., where there are strong winds), the solar module 100 is easily damaged and even broken in the frame 160 as a result of undergoing excessive bending.

### SUMMARY

An aspect of the present invention is to provide a solar module.

In an embodiment of the present invention, a solar module includes a support element, a frame body, a photoelectric conversion module, and a protection element. An accommodating space is formed in a region surrounded by the frame body. The photoelectric conversion module is located in the accommodating space. The support element extends past the photoelectric conversion module and is connected to the frame body. The protection element is located on the photoelectric conversion module, and is located in the accommodating space.

In an embodiment of the present invention, the photoelectric conversion module includes a first package element, a photoelectric conversion element, and a second package element. The photoelectric conversion element is mounted on the first package element. The second package element is mounted on the photoelectric conversion element. The first package element is adhered on the support element, and the second package element is adhered on the protection element.

In an embodiment of the present invention, the support element is a mesh body, and a portion of the first package element is embedded in the mesh body.

In an embodiment of the present invention, the support element includes a mesh structure located between the frame body and the photoelectric conversion module, and the mesh structure is located outside the projected area of the photoelectric conversion module.

In an embodiment of the present invention, the solar module further includes a sealant located on the edge of the protection element and the edge of the photoelectric conversion module.

In an embodiment of the present invention, the solar module further includes a third package element adhered to the support element. The third package element and the first package element are respectively located on two opposite sides of the support element.

In an embodiment of the present invention, the support element includes a plurality of through holes, and the third package element and the first package element are connected via the through holes.

In an embodiment of the present invention, the solar module further includes a protection layer mounted on the third package element.

In an embodiment of the present invention, the solar module further includes a sealant located on the edge of the third package element and the edge of the protection layer.

In an embodiment of the present invention, the thickness of the support element is in a range between 1 and 5 mm.

In an embodiment of the present invention, the length of the support element is greater than the length of the photoelectric conversion module, and is greater than the length of the protection element, and the frame body includes a fastening groove in which the edge of the support element is inserted, such that a distance is formed between the photoelectric conversion module and the frame body, and is formed between the protection element and the frame body.

In an embodiment of the present invention, the solar module further includes a fixing element extending through the support element and fixed on the frame body.

In the aforementioned embodiments of the present invention, since the edge of the support element is surrounded and coupled to the frame body, and the photoelectric conversion module is located on the support element, the support element can provide the solar module with sufficient rigidity, such that a conventional protection glass can be omitted from the configuration of the solar module. As a result, the weight of the solar module can be reduced and the solar module can be easily installed. Moreover, the support element may be a mesh body so as to have flexibility. When the solar module is used in a harsh environment (e.g., where there are strong winds), air can pass through the through holes of the support element, such that the photoelectric conversion module is not easily broken in the frame body as a result of undergoing excessive bending.

### BRIEF DESCRIPTION OF THE DRAWINGS

FIG. 1 is a cross-sectional view of a conventional solar module;

FIG. 2 is a top view of a solar module according an embodiment of the present invention;

FIG. 3 is a cross-sectional view of the solar module taken along line 3-3′ shown in FIG. 1;

FIG. 4 is a cross-sectional view of the solar module shown in FIG. 3 when subjected to airflows;

FIG. 5 is a cross-sectional view of a solar module according an embodiment of the present invention;

FIG. 6 is a cross-sectional view of a solar module according an embodiment of the present invention;

FIG. 7 is a cross-sectional view of a solar module according an embodiment of the present invention;

FIG. 8 is a cross-sectional view of a solar module according an embodiment of the present invention; and

FIG. 9 is a cross-sectional view of a solar module according an embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

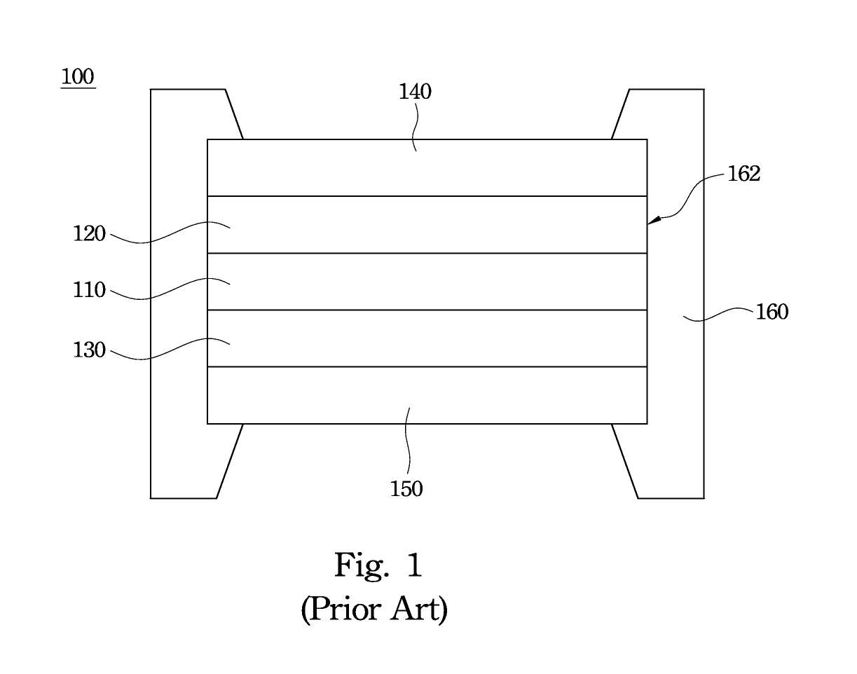

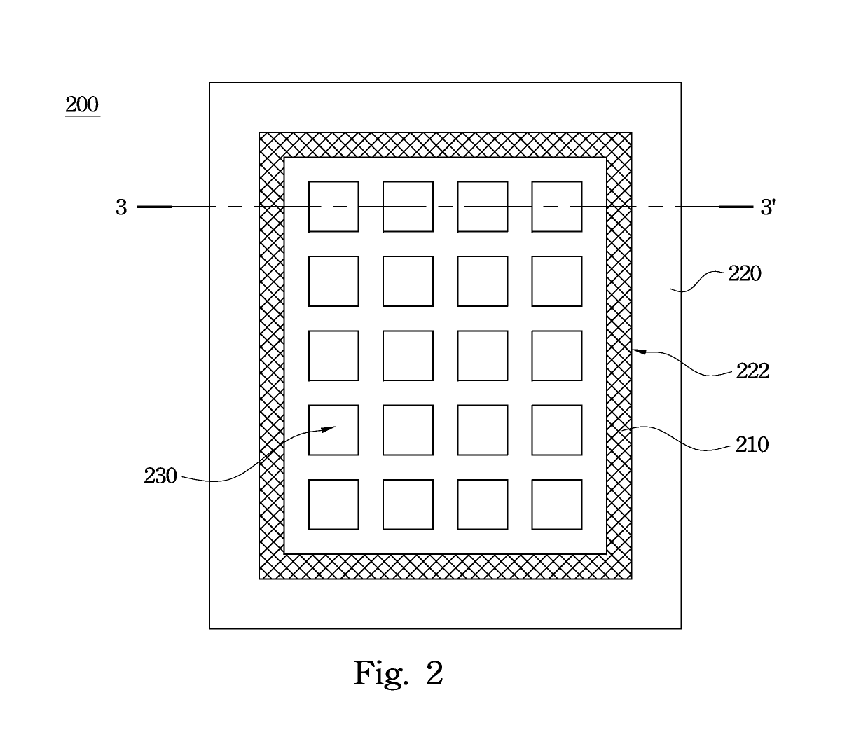

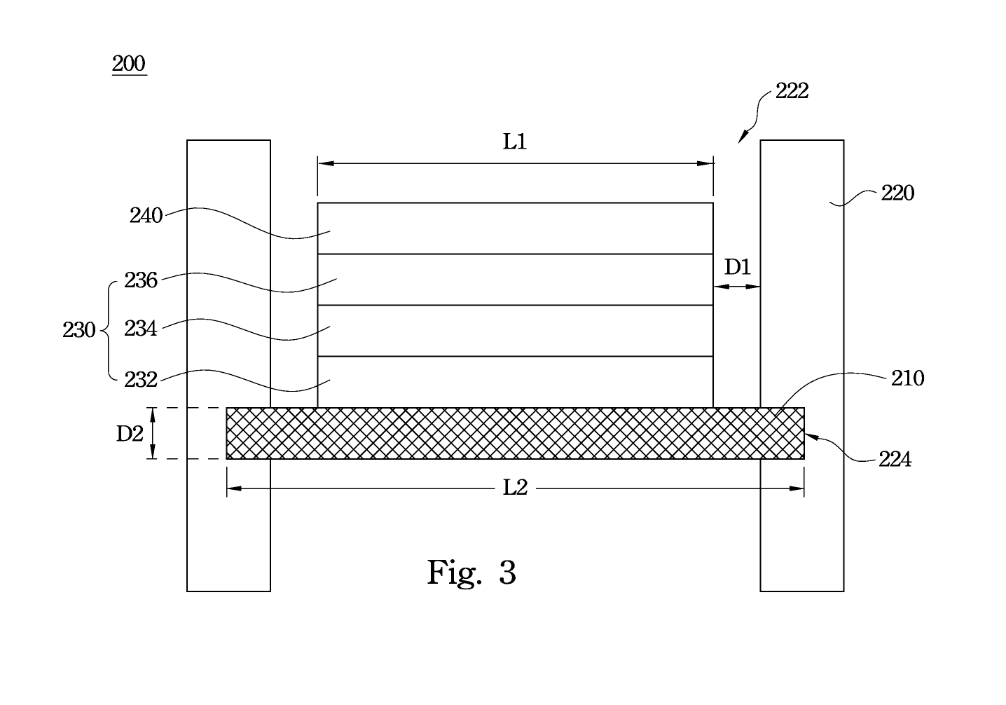

FIG. 2 is a top view of a solar module 200 according an embodiment of the present invention. FIG. 3 is a cross-sectional view of the solar module 200 taken along line 3-3′ shown in FIG. 1. As shown in FIG. 2 and FIG. 3, the solar module 200 includes a support element 210, a frame body 220, a photoelectric conversion module 230, and a protection element 240. The edge of the support element 210 is surrounded and coupled to the frame body 220, and an accommodating space 222 is formed in a region surrounded by the frame body 220. The support element 210 extends past the photoelectric conversion module 230 and is connected to the frame body 220. The photoelectric conversion module 230 is mounted on the support element 210, and is located in the accommodating space 222. The protection element 240 is mounted on the photoelectric conversion module 230, and is located in the accommodating space 222.

In this embodiment, the photoelectric conversion module 230 includes a first package element 232, a photoelectric conversion element 234, and a second package element 236. The photoelectric conversion element 234 is mounted on the first package element 232. The second package element 236 is mounted on the photoelectric conversion element 234. The first package element 232 is adhered on the support element 210, and the second package element 236 is adhered on the protection element 240.

Furthermore, the length L2 of the support element 210 is greater than the length L1 of the photoelectric conversion module 230, and is greater than the length L1 of the protection element 240. The frame body 220 includes a fastening groove 224, and the edge of the support element 210 is inserted into the fastening groove 224 so that the support element 210 is coupled to the frame body 220. With this configuration, a distance D1 is formed between the photoelectric conversion module 230 and the frame body 220, as well as between the protection element 240 and the frame body 220. In other embodiments, the photoelectric conversion module 230 and the protection element 240 can be separated from the frame body 220 respectively with two different distances, and the present invention is not limited in this regard.

The support element 210 may be a mesh body, such that a portion of the first package element 232 can be embedded in the mesh body. As a result of being made of a mesh body, the support element 210 has a plurality of through holes. The support element 210 may be made of a material that includes glass fiber, stainless steel, plant fiber, carbon fiber, or polymer fiber. The stainless steel may undergo an insulation treatment. The polymer fiber may be polyamide fiber, polyethylene terephthalate (PET) fiber, or polyvinyl chloride (PVC) fiber.

Since the edge of the support element 210 is surrounded by and coupled to the frame body 220, and the photoelectric conversion module 230 is mounted on the support element 210, the support element 210 can provide the solar module 200 sufficient rigidity, such that a conventional protection glass can be omitted from the configuration of the solar module 200. As a result, the weight of the solar module 200 can be reduced and the solar module 200 can be easily installed.

Moreover, since the support element 210 is not easily broken and the support element 210 may be a flexible mesh body, when the photoelectric conversion module 230 and the protection element 240 are subjected to an external force (e.g., a wind force), the support element 210 can cushion the external force. That is to say, when the protection element 240 is presses by an external force, the photoelectric conversion module 230 and the protection element 240 can be moved a distance up and down by the flexible support element 210 in the accommodating space 222 of the frame body 220. Moreover, when the solar module 200 is used in a harsh environment (e.g., where there are strong winds), air can pass through the through holes of the support element 210, such that the photoelectric conversion element 234 is not easily broken in the frame body 220 as a result of undergoing excessive bending (as described hereinafter).

In this embodiment, the protection element 240 is light transmissive, such that a light can enter into the photoelectric conversion module 230 through the protection element 240. The protection element 240 may be made of a material that includes plastic, fluoride, or polymer film. In practice, other materials having characteristics such as high transparency, low weight, and flexibility can also be used to manufacture the protection element 240. The first package element 232 may be made of ethylene vinyl acetate (EVA) or silicone. The second package element 236 may be made of ethylene vinyl acetate or silicone. The second package element 236 may have the same material as the first package element 232. In addition, the thickness D2 of the support element 210 may be in a range between 1 and 5 mm. The thickness D2 is 2 mm in this embodiment. The thickness of the protection element 240 may be in a range between 50 and 200 μm. The thickness of the photoelectric conversion module 230 may be in a range between 980 and 1200 μm. Each of the thicknesses of the first and second package elements 232, 236 may be in a range between 0.4 and 0.5 mm. However, the present invention is not limited to the aforementioned thicknesses, and each of the thicknesses can be decided by designers as they deem necessary.

The photoelectric conversion module 230 may include amorphous silicon, single crystal silicon, poly silicon, cadmium diselenide (CdS), cadmium telluride (CdTe), copper indium selenide (CIS), or copper indium gallium diselenide (CIGS), but the present invention is not limited in this regard. Furthermore, the photoelectric conversion module 230 may be formed by a method of chemical vapor deposition (CVD), physical vapor deposition (PVD), sputter deposition, or using other deposition techniques.

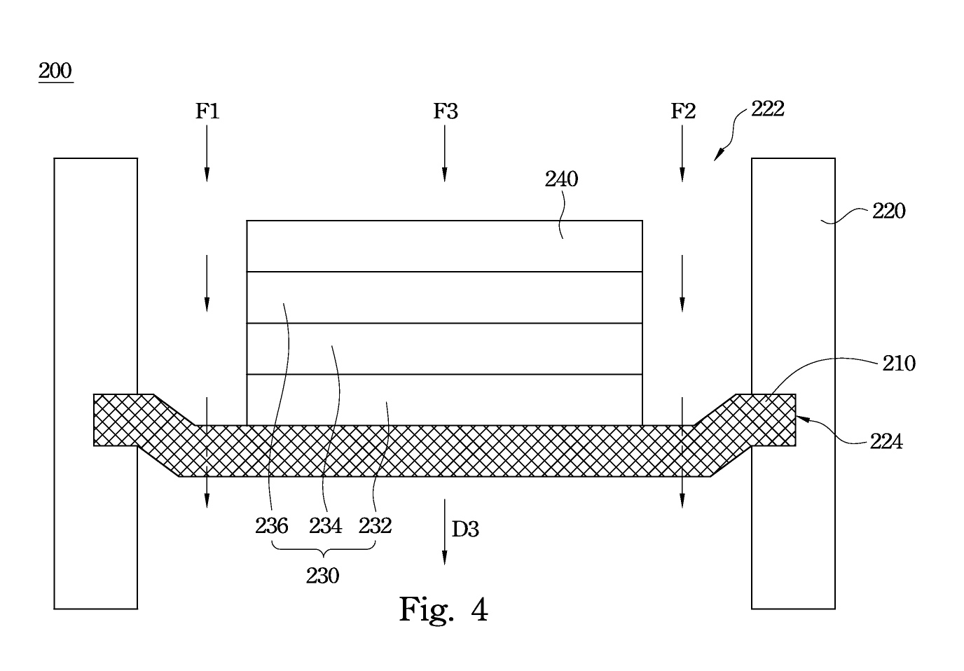

FIG. 4 is a cross-sectional view of the solar module 200 shown in FIG. 3 when subjected to airflows F1, F2, and F3. As shown in FIG. 4, the support element 210 is flexible when it is a mesh body. When the photoelectric conversion module 230 and the protection element 240 are subjected to the airflow F3, the photoelectric conversion module 230 and the protection element 240 can be moved a distance in a direction D3 in the accommodating space 222 of the frame body 220 due to the airflow F3 acting directly on the protection element 240. Therefore, the support element 210 can cushion the external force that is acting on the solar module 200.

Moreover, since the support element 210 includes the through holes, air forming the airflows F1, F2 between the photoelectric conversion module 230 and the frame body 220 can pass through the through holes of the support element 210, such that the force generated by the airflows F1, F2 acting on the solar module 200 can be significantly reduced. As a result, essentially only the airflow F3 acts on the solar module 200, such that the photoelectric conversion element 234 is not easily broken in the frame body 220 as a result of undergoing excessive bending. In this embodiment, the airflows F1, F2, F3 are wind forces generated by the environment. However, in other embodiments, the support element 210 can cushion other kinds of external forces, and the present invention is not limited to cushioning only wind forces.

It is to be noted that the connection relationship of the aforementioned elements will not be repeated in the following description, and only aspects related to other fixing methods and structures of the solar module 200 will be described.

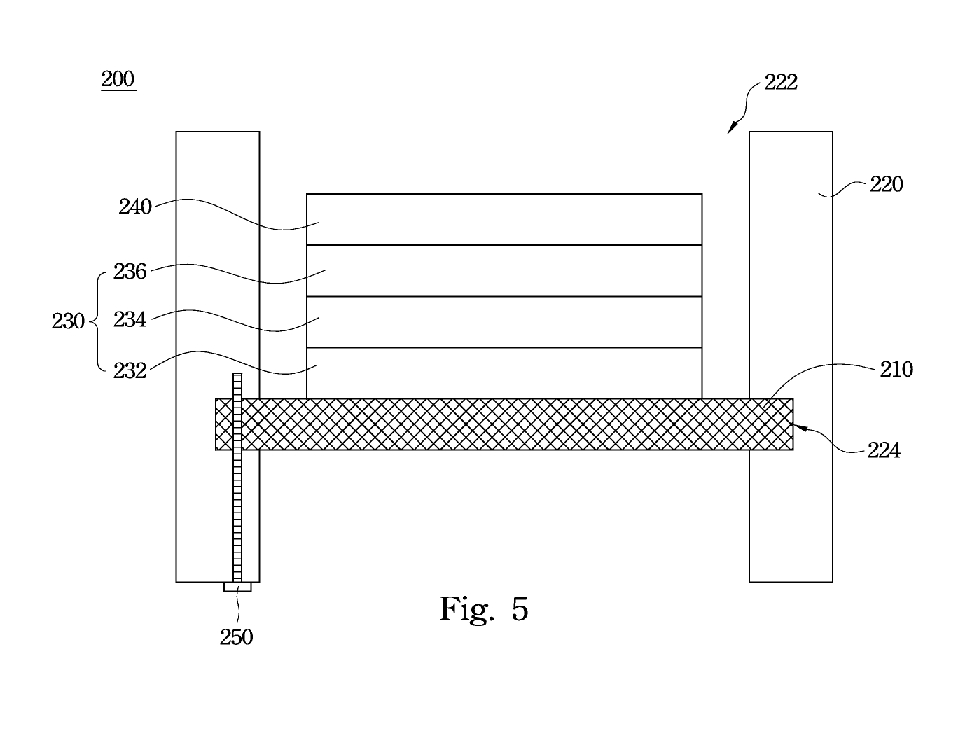

FIG. 5 is a cross-sectional view of a solar module 200 according an embodiment of the present invention. The solar module 200 includes the support element 210, the frame body 220, the photoelectric conversion module 230, and the protection element 240. The difference between this embodiment and the aforementioned embodiment is that the solar module 200 further includes a fixing element 250 extending through the support element 210 and fixed on the frame body 220. Consequently, the support element 210 can be fixed firmly on the frame body 220.

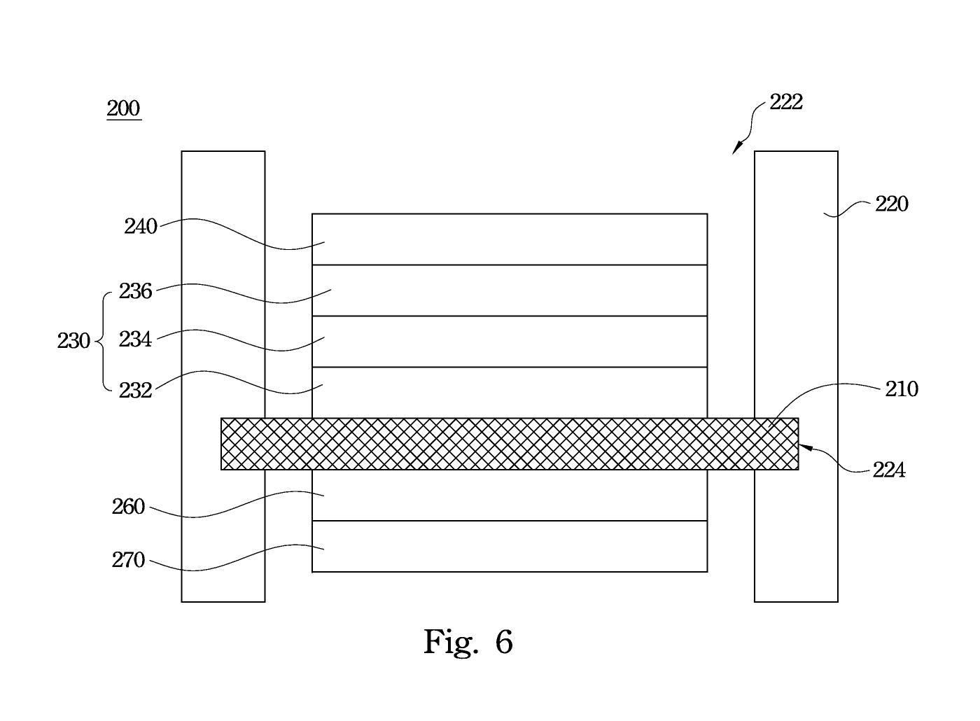

FIG. 6 is a cross-sectional view of a solar module 200 according an embodiment of the present invention. The solar module 200 includes the support element 210, the frame body 220, the photoelectric conversion module 230, and the protection element 240. The difference between this embodiment and the aforementioned embodiment is that the solar module 200 further includes a third package element 260 and a protection layer 270. The third package element 260 is adhered to the support element 210, and the third package element 260 and the first package element 232 are respectively located on two opposite sides of the support element 210. The protection layer 270 is mounted on the third package element 260. Furthermore, the support element 210 includes a plurality of through holes, such that the third package element 260 and the first package element 232 can be connected via the through holes.

In this embodiment, the protection layer 270 may be made of a material that includes polyvinyl fluoride (PVF) or polyethylene terephthalate (PET) coating fluoride layer. The material of the third package element 260 can be the same as the first package element 232, such as ethylene vinyl acetate or silicone. Moreover, the thickness of the protection layer 270 may be in a range between 0.3 and 0.4 mm, and the thickness of the third package element 260 may be in a range between 0.4 and 0.5 mm. However, the present invention is not limited to the aforementioned thicknesses, and each of the thicknesses can be decided by designers as they deem necessary.

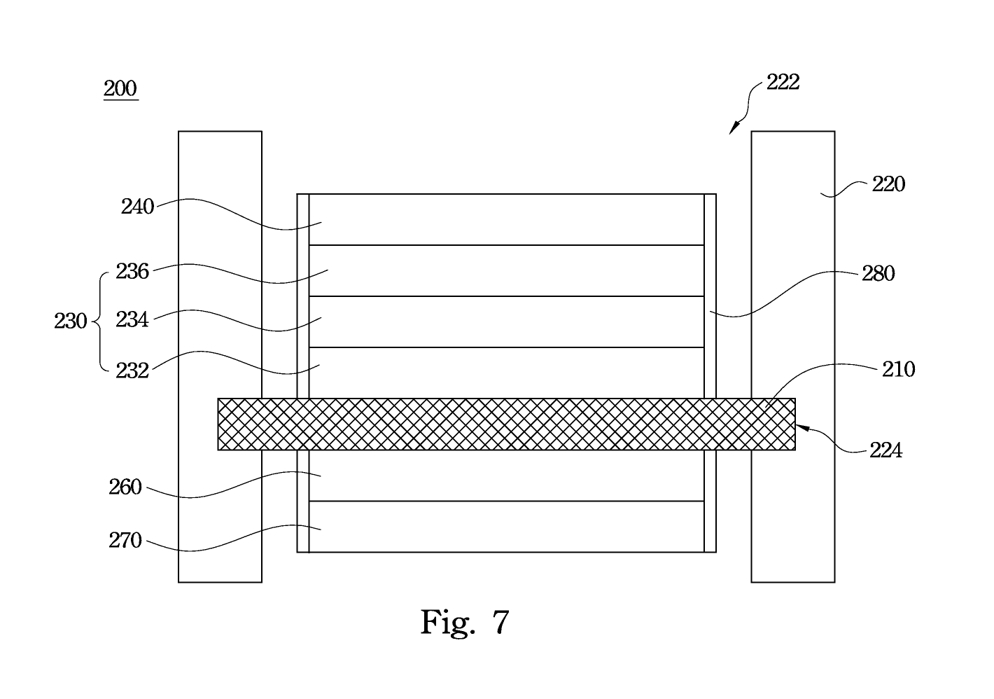

FIG. 7 is a cross-sectional view of a solar module 200 according an embodiment of the present invention. The solar module 200 includes the support element 210, the frame body 220, the photoelectric conversion module 230, the protection element 240, the third package element 260, and the protection layer 270. The difference between this embodiment and the aforementioned embodiment is that the solar module 200 further includes a sealant 280 located on the edges of the protection element 240, the photoelectric conversion module 230, the third package element 260, and the protection layer 270. The position of the sealant 280 can be decided by designers as needed. For example, the sealant 280 can be applied only to the edges of the protection element 240 and the photoelectric conversion module 230, but not to the edges of the third package element 260 and the protection layer 270.

In this embodiment, the sealant 280 may be made of a material that includes rubber or silicone. The sealant 280 can prevent moisture from entering the photoelectric conversion element 234 through the edges of the protection element 240, the photoelectric conversion module 230, the third package element 260, and the protection layer 270.

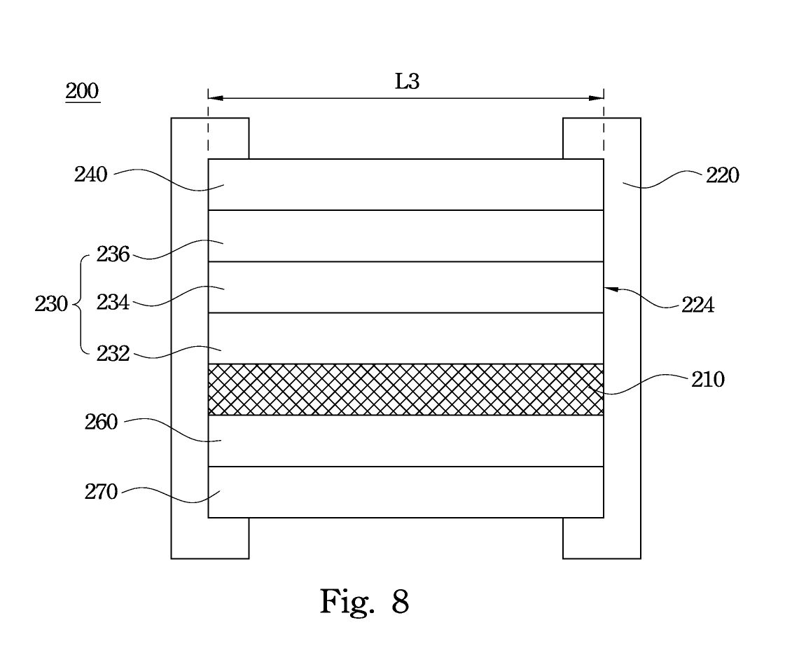

FIG. 8 is a cross-sectional view of a solar module 200 according an embodiment of the present invention. The solar module 200 includes the support element 210, the frame body 220, the photoelectric conversion module 230, the protection element 240, the third package element 260, and the protection layer 270. The difference between this embodiment and the aforementioned embodiment is that the lengths L3 of the support element 210, the photoelectric conversion module 230, the protection element 240, the third package element 260, and the protection layer 270 are substantially the same. Furthermore, the frame body 220 includes the fastening groove 224 coupled to the edges of the support element 210, the photoelectric conversion module 230, the protection element 240, the third package element 260, and the protection layer 270.

In this embodiment, since the edges of the support element 210, the photoelectric conversion module 230, the protection element 240, the third package element 260, and the protection layer 270 are covered by the frame body 220, moisture does not easily enter the photoelectric conversion element 234. Therefore, the sealant 280 shown in FIG. 7 can be omitted from the configuration of the solar module 200 of this embodiment.

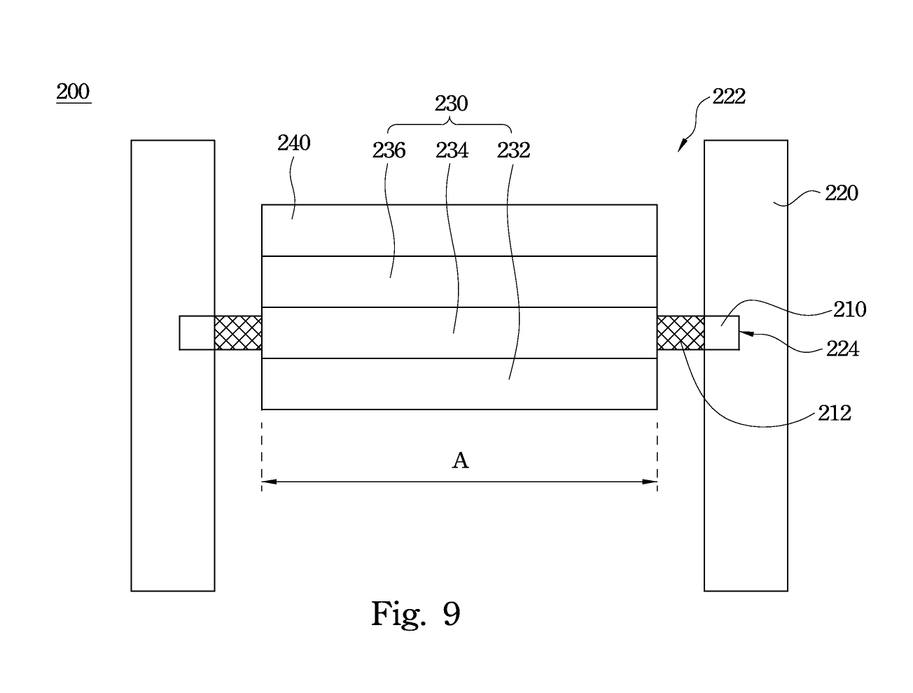

FIG. 9 is a cross-sectional view of a solar module 200 according an embodiment of the present invention. The solar module 200 includes the support element 210, the frame body 220, the photoelectric conversion module 230, and the protection element 240. The difference between this embodiment and the aforementioned embodiment is that the support element 210 includes a mesh structure 212 located between the frame body 220 and the photoelectric conversion module 230, and the mesh structure 212 is not located under the projected area A of the photoelectric conversion module 230 (i.e., the mesh structure is located outside the projected area A of the photoelectric conversion module 230). Since the mesh structure 212 is flexible, the support element 210 can cushion an external force acting on the solar module 200. Moreover, air that forms an airflow can pass through the through holes of the mesh structure 212, such that the photoelectric conversion element 234 is not easily broken in the frame body 220 as a result of undergoing excessive bending.

Compared with a conventional solar module, since the edge of the support element is surrounded and coupled to the frame body, and the photoelectric conversion module is located on the support element, the support element can provide the solar module with sufficient rigidity, such that a conventional protection glass can be omitted from the configuration of the solar module. As a result, the weight of the solar module can be reduced and the solar module can be easily installed. Moreover, the support element may be a mesh body so as to have flexibility. When the solar module is used in a harsh environment (e.g., where there are strong winds), air can pass through the through holes of the support element, such that the photoelectric conversion module is not easily broken in the frame body as a result of undergoing excessive bending.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A solar module comprising:
a frame body, wherein an accommodating space is formed in a region surrounded by the frame body;
a photoelectric conversion module located in the accommodating space;
a support element extending past the photoelectric conversion module and connected to the frame body; and
a protection element disposed on the photoelectric conversion module and located in the accommodating space.

2. The solar module as claimed in claim 1, wherein the photoelectric conversion module comprises:
a first package element;
a photoelectric conversion element disposed on the first package element; and
a second package element disposed on the photoelectric conversion element;
wherein the first package element is adhered on the support element, and the second package element is adhered on the protection element.

3. The solar module as claimed in claim 2, wherein the support element is a mesh body, and a portion of the first package element is embedded in the mesh body.

4. The solar module as claimed in claim 1, wherein the support element comprises a mesh structure located between the frame body and the photoelectric conversion module, and the mesh structure is located outside the projected area of the photoelectric conversion module.

5. The solar module as claimed in claim 1, further comprising:
a sealant located on the edge of the protection element and the edge of the photoelectric conversion module.

6. The solar module as claimed in claim 2, further comprising:
a third package element adhered to the support element, wherein the third package element and the first package element are respectively located on two opposite sides of the support element.

7. The solar module as claimed in claim 6, wherein the support element comprises a plurality of through holes, and the third package element and the first package element are connected via the through holes.

8. The solar module as claimed in claim 7, further comprising:
a protection layer disposed on the third package element.

9. The solar module as claimed in claim 8, further comprising:
a sealant located on the edge of the third package element and the edge of the protection layer

10. The solar module as claimed in claim 1, wherein the thickness of the support element is in a range between 1 and 5 mm.

11. The solar module as claimed in claim 1, wherein the length of the support element is greater than the length of the photoelectric conversion module, and is greater than the length of the protection element, and the frame body comprises a fastening groove in which the edge of the support element is inserted, such that a distance is formed between the photoelectric conversion module and the frame body, and is formed between the protection element and the frame body.

12. The solar module as claimed in claim 1, further comprising:
a fixing element extending through the support element and fixed on the frame body.
